(19) United States
(12) Patent Application Publication
(10) Pub. No.: US 2017/0048974 A1
(43) Pub. Date: Feb. 16, 2017

(54) RESIN COMPOSITION FOR PERMANENT INSULATING FILM, PERMANENT INSULATING FILM, MULTILAYER PRINTED WIRING BOARD, AND PROCESS FOR PRODUCING THE SAME

(71) Applicant: TAIYO INK MFG. CO., LTD., Hiki-gun (JP)

(72) Inventors: Touko SHIINA, Hiki-gun (JP); Shoji MINEGISHI, Hiki-gun (JP)

(73) Assignee: TAIYO INK MFG. CO., LTD., Hiki-gun (JP)

(21) Appl. No.: 15/306,300

(22) PCT Filed: Mar. 19, 2015
(86) PCT No.: PCT/JP2015/058361

§ 371 Date: Oct. 24, 2016

(30) Foreign Application Priority Data
Apr. 25, 2014 (JP) 2014-091356

(51) Int. Cl. H05K 1/03; H05K 3/00; H05K 3/46; H05K 3/42; H05K 1/02; H05K 1/11

(52) U.S. Cl. CPC H05K 1/0353; H05K 1/0298; H05K 1/115; H05K 3/46; H05K 3/429; H05K 3/0047

(57) ABSTRACT

A resin composition for a permanent insulating film is provided, by which, in particular, partial through-holes obtained by partitioning a through-hole can be easily and precisely formed as designed without a deposition of catalytic species (seed) in a plating resist portion. The present invention provides a resin composition for a permanent insulating film, including a thermosetting resin, a resin filler, and a compound containing at least one atom selected from a sulfur atom and a nitrogen atom. The present invention also provides a multilayer printed wiring board in which conductive layers having a circuit pattern and insulation layers are alternately overlaid with each other, and a through-hole enabling electric conductivity among conductive layers via a through-hole. The through-hole includes a plating resist portion provided on either of an interlaminar part between the conductive layer and the insulation layer or another interlaminar part between the insulation layers, or both. The plating portion(s) is/are provided on the interlaminar parts which had been exposed in an opening as the through-hole, and on an exposed region other than the plating resist portion, and the plating resist portion is made of a cured product of the resin composition.

### TECHNICAL FIELD

The present invention relates to a resin composition for a permanent insulating film, a permanent insulating film (plating resist) made of a cured product of the resin composition, a multilayer printed wiring board produced by using the same, and a process for producing the same. In particular, the present invention relates to a multilayer printed wiring board having partial through-holes, which are in the form of through-holes partitioned with a partial plating resist in a through-hole.

### BACKGROUND ART

In general, a printed wiring board has a patterned conductor circuit for connecting components provided on the outer or inner surface layer of the wiring board, based on a circuit design. Electronic components are mounted by soldering on the surface of the wiring board. In response to the recent miniaturization of electronic appliances such as mobile phones, mobile electronic terminals, or computers, there are such demand for the increased density of printed wiring boards for use in such electronic appliances.

On the other and, a multilayer printed wiring board is used for high density component-packing and high-definition circuit wiring. For the purpose, the multilayer printed wiring board is configured to have a resin insulation layer(s) and conductor circuit layer(s), which are alternately overlaid with one another. A plurality of the conductor circuit layers is electrically connected via a through-hole.

For manufacturing such a multilayer printed wiring board, resin insulation layers and conductor circuit layers are alternately overlaid with one another on a substrate to give a wiring board, and then the through-hole is prepared by making a hole with a drill or the like in the wiring board, with plating process thereafter. Usually, in the plating treatment, the through-hole is entirely plated with a conductive substance.

In the entirely plated through-hole, a certain portion which should not have had electric connection among conductor circuit layers, if any, is possibly plated with the conductive substance. Such undesired plating might interfere with the maintainability of signal transduction.

In this respect, a technology for achieving a complicated circuit pattern has been proposed, wherein a through-hole is partitioned with a plating resist portion(s) to prepare a non-connection portion (a portion for which signal transduction is unnecessary) among conductor circuit layers within the through-hole.

For example, a multilayer printed wiring board has been proposed which has a subcomposite structure, having a nonconductive dielectric layer provided between conductive layers. The conductive layers contain a gap filled with a plating resist, and a through-hole penetrating through the plating resist. The wiring board has a via structure partitioned by a portion(s) free from the plating resist, which is/are plated with a conductive material (see Patent Literature 1).

Multilayer printed wiring boards such as those described in Patent Literature 1 are designed to have, in the via structure, one or more voids, free from the application of a conductive material thereto. As a result, this makes it possible to limit the application of the conductive material, in the via structure, only to necessary regions for the transmission of electric signals.

In Patent Literature 1, examples of the plating resist for use in the production of the multilayer printed wiring board include hydrophobic insulating materials such as silicone resins, polyethylene resins, fluorocarbon resins, polyurethane resins, and acrylic resins. It is stated in the literature that the application of hydrophobic insulating materials as the plating resist help to prevent the deposition of catalytic species (seed).

### PRIOR ART LITERATURE

### Patent Literature

Patent Literature 1: JP-A 2008-532326

### SUMMARY OF INVENTION

### Problems to be Solved by the Invention

Patent Literature 1 includes a discussion that the hydrophobicity of a plating resist prevents deposition of catalytic species (seed). The literature, however, states that the deposit cannot be completely prevented, and that it is necessary to remove a residual deposition by after-treatment operation if the deposition is found even in a small amount. Therefore, there is a demand for further improving the plating resist in the through-hole.

A main object of the present invention is to provide a resin composition for a permanent insulating film, by which a through-hole, particularly, a partial through-hole, i.e., a partitioned through-hole can be formed easily and precisely as designed, without a deposition of catalytic species (seed) in a plating resist portion of the permanent insulating film.

Another object of the present invention is to provide a multilayer printed wiring board in which a partial through-hole, i.e., a partitioned through-hole is formed precisely as designed, without an unwanted plating attached to a plating resist portion of the permanent insulating film.

A further alternative object of the present invention is to provide a method for producing a multilayer printed wiring board.

### Means for Solving the Problems

The inventors of the present invention have conducted diligent studies to attain the objects and consequently completed the present invention including the structures described below.

Specifically, the resin composition for a permanent insulating film of the present invention comprises a thermosetting resin, a resin filler, and a compound containing at least one atom selected from a sulfur atom and a nitrogen atom. The resin in the resin filler is preferably a hydrophobic resin. The compound containing at least one atom selected from a sulfur atom and a nitrogen atom is preferably at least one compound selected from a heterocyclic compound, an aliphatic thiol, and a disulfide compound.

The resin composition for a permanent insulating film of the present invention is preferably used for preparing a plating resist portion in a printed wiring board. The printed wiring board comprises conductive layers of circuit patterns and insulation layers which are alternately overlaid with one another. The plating resist portion is prepared in the above-mentioned opening as a through-hole in the printed wiring board, by applying the resin composition to at least one of interlaminar parts, exposed in the opening as a through-hole. The interlaminar parts include an interlaminar part between a conductive layer and the insulation layer, and an interlaminar part between insulation layers.

The permanent insulating film of the present invention is composed of a cured product of the aforementioned resin composition of the present invention. The printed wiring board of the present invention has this permanent insulating film, preferably a plating resist portion composed of this permanent insulating film. Particularly in a multilayer printed wiring board, which comprises conductive layers of circuit patterns and insulation layers, having the conductive layers and the insulation layers alternately overlaid with one another, and a through-hole for having electric conduction among conductive layers, the through-hole has a plating resist portion provided on at least one of exposed parts of interlaminar parts, including an interlaminar part between a conductive layer and the insulation layer, and an interlaminar part among insulation layers, to provide the plating resist portion, and a plating portion formed in an exposed region other than the plating resist portion. The plating resist portion is composed of a cured product (permanent insulating film) of the aforementioned resin composition of the present invention.

The method for producing a multilayer printed wiring board according to the present invention comprises a step of preparing a multilayer wiring board in the form of a laminate comprising conductive layers of circuit patterns and insulation layers, which are alternately laminated with each other, an opening as a through-hole in the laminate, and a plating resist portion prepared from the resin composition according to the present invention, which is provided on at least one of interlaminar parts exposed forming the opening as a through-hole, the interlaminar parts including:
an interlaminar part between a conductive layer and the insulation layer, and
an interlaminar part between insulation layers, and the applying hot-press to the layers including the conductive layers of the a circuit pattern and the plating resist portion provided at the at least one of interlaminar parts.

The method of the present invention further comprises a step of preparing a through-hole on the multilayered wiring board which penetrates the plating resist portion by use of a drill or a laser; a step of subjecting the opening as a through-hole to a desmear treatment; and a step of subjecting the desmeared opening as a through-hole to a plating treatment.

### Effects of Invention

According to the present invention, a resin composition for a permanent insulating film is provided, which assures the elimination of plating and is excellent in resistance to a plating solution. As a result, it is possible in the present invention to provide a multilayer printed wiring board in which, a through-hole, particularly, a partial through-hole, i.e, partitioned through-hole is easily formed in a good preciseness as designed.

Furthermore, it is possible to minimize an adverse effect (stub effect) to signals, which could be caused by an unnecessary conductor portion in a through-hole, particularly, in the multilayer printed wiring board having partial through-holes, i.e., a partitioned through-hole.

### BRIEF DESCRIPTION OF DRAWINGS

FIG. 1 is a cross-sectional schematic view of a multilayer printed wiring board, for illustrating the preparation course of a through-hole in the multilayer printed wiring board by using the resin composition for a permanent insulating film, as an embodiment of the present invention.

FIG. 2 is a cross-sectional schematic view of a multilayer printed wiring board, for illustrating the preparation course of a through-hole in the multilayer printed wiring board by using the resin composition for a permanent insulating film, as a further embodiment of the present invention.

FIG. 3 is a cross-sectional schematic view of a multilayer printed wiring board, for illustrating the preparation course of a through-hole in the multilayer printed wiring board by using the resin composition for a permanent insulating film as a further embodiment of the present invention.

FIG. 4 is a cross-sectional schematic view of a conventional multilayer printed wiring board, for illustrating the preparation course, to the midpoint, of a through-hole in the conventional multilayer printed wiring board.

FIG. 5 is a cross-sectional schematic view of the conventional multilayer printed wiring board of FIG. 4, for illustrating the remaining preparation course of a through-hole in the conventional multilayer printed wiring board.

FIG. 6 is a cross-sectional schematic view of a multilayer printed wiring board, for illustrating the preparation course of the multilayer printed wiring board in accordance with a conventional buildup method.

### BRIEF DESCRIPTION OF DRAWINGS

Hereinafter, the present invention will be described in detail.

First, the resin composition for a permanent insulating film of the present invention will be described.

The resin composition for a permanent insulating film of the present invention comprises a thermosetting resin, a resin filler, and a compound containing at least one of a sulfur atom and a nitrogen atom. Particularly, the resin composition for a permanent insulating film of the present invention is suitable for the purpose of forming a plating resist portion provided on at least one of the interlaminar parts including an interlaminar part between a conductive layer and an insulation layer or at an interlaminar part between insulation layers, exposed in an opening as a through-hole, in a printed wiring board in which conductive layers having a circuit pattern and insulation layers are alternately overlaid.

In the resin composition for a permanent insulating film of the present invention, the thermosetting resin plays a role of imparting adhesion to a substrate (base material), etc. A commonly-used thermosetting resin known in the art including amino resins such as melamine resins, benzoguanamine resins, melamine derivatives, and benzoguanamine derivatives, block isocyanate compounds, cyclocarbonate compounds, polyfunctional epoxy compounds, polyfunctional oxetane compounds, episulfide resins, bismaleimide, and carbodiimide resins can be used as the thermosetting resins. Among others, a thermosetting resin having, in the molecule, at least one of: a plurality of cyclic ether groups and cyclic thioether groups (hereinafter, referred to as cyclic (thio)ether groups) is particularly preferred because of producing low cure shrinkage and high adhesion. Such a thermosetting resin having a plurality of cyclic (thio)ether groups in the molecule is a compound having a plurality of 3-, 4-, or 5-membered cyclic (thio)ether groups of any one type or two types in the molecule. Examples of the resin include: a compound having a plurality of epoxy groups in the molecule, i.e., a polyfunctional epoxy compound; a compound having a plurality of oxetanyl groups in the molecule, i.e., a polyfunctional oxetane compound; and a compound having a plurality of cyclic thioether groups in the molecule, i.e., an episulfide resin.

Examples of the polyfunctional epoxy compound include, but are not limited to: epoxidized plant oils such as ADK CIZER O-130P, ADK CIZER O-180A, ADK CIZER D-32, and ADK CIZER D-55 manufactured by ADEKA Corp.; bisphenol A-type epoxy resins such as jER828, jER834, jER1001, and jER1004 manufactured by Mitsubishi Chemical Corporation, EHPE3150 manufactured by Daicel Corp, EPICLON 840, EPICLON 850, EPICLON 1050, and EPICLON 2055 manufactured by DIC Corp., EPOTOHTO YD-011, YD-013, YD-127, and YD-128 manufactured by Tohto Kasei Co., Ltd., D.E.R.317, D.E.R.331, D.E.R.661, and D.E.R.664 manufactured by The Dow Chemical Company, SUMI-EPOXY ESA-011, ESA-014, ELA-115, and ELA-128 manufactured by Sumitomo Chemical Co., Ltd., and A.E.R.330, A.E.R.331, A.E.R.661, and A.E.R.664 manufactured by Asahi Kasei Corp. (all are product names); YDC-1312, hydroquinone-type epoxy resins, YSLV-80XY bisphenol-type epoxy resins, and YSLV-120TE thioether-type epoxy resins (all manufactured by Tohto Kasei Co., Ltd.); brominated epoxy resins such as jERYL903 manufactured by Mitsubishi Chemical Corporation, EPICLON 152 and EPICLON 165 manufactured by DIC Corp., EPOTOHTO YDB-400 and YDB-500 manufactured by Tohto Kasei Co., Ltd., D.E.R.542 manufactured by The Dow Chemical Company, SUMI-EPOXY ESB-400 and ESB-700 manufactured by Sumitomo Chemical Co., Ltd., and A.E.R.711 and A.E.R.714 manufactured by Asahi Kasei Corp. (all are product names); novolac-type epoxy resins such as jER152 and jER154 manufactured by Mitsubishi Chemical Corporation, D.E.N.431 and D.E.N.438 manufactured by The Dow Chemical Company, EPICLON N-730, EPICLON N-770, and EPICLON N-865 manufactured by DIC Corp., EPOTOHTO YDCN-701 and YDCN-704 manufactured by Tohto Kasei Co., Ltd., EPPN-201, EOCN-1025, EOCN-1020, EOCN-104S, and RE-306 manufactured by Nippon Kayaku Co., Ltd., SUMI-EPOXY ESCN-195X and ESCN-220 manufactured by Sumitomo Chemical Co., Ltd., and A.E.R.ECN-235 and ECN-299 manufactured by Asahi Kasei Corp. (all are product names); biphenol novolac-type epoxy resins such as NC-3000 and NC-3100 manufactured by Nippon Kayaku Co., Ltd.; bisphenol F-type epoxy resins such as EPICLON 830 manufactured by DIC Corp., jER807 manufactured by Mitsubishi Chemical Corporation, and EPOTOHTO YDF-170, YDF-175, and YDF-2004 manufactured by Tohto Kasei Co., Ltd. (all are product names); hydrogenated bisphenol A-type epoxy resins such as EPOTOHTO ST-2004, ST-2007, and ST-3000 manufactured by Tohto Kasei Co., Ltd. (all are product names); glycidylamine-type epoxy resins such as jER604 manufactured by Mitsubishi Chemical Corporation, EPOTOHTO YH-434 manufactured by Tohto Kasei Co., Ltd., and SUMI-EPOXY ELM-120 manufactured by Sumitomo Chemical Co., Ltd. (all are product names); hydantoin-type epoxy resins; alicyclic epoxy resins such as CELLOXIDE 2021 (product name) manufactured by Daicel Corp.; trihydroxyphenyl methane-type epoxy resins such as YL-933 manufactured by Mitsubishi Chemical Corporation, and T.E.N., EPPN-501, and EPPN-502 manufactured by The Dow Chemical Company (all are product names); bixylenol-type or biphenol-type epoxy resins or mixtures thereof, such as YL-6056, YX-4000, and YL-6121 manufactured by Mitsubishi Chemical Corporation (all are product names); bisphenol S-type epoxy resins such as EBPS-200 manufactured by Nippon Kayaku Co., Ltd., EPX-30 manufactured by ADEKA Corp., and EXA-1514 manufactured by DIC Corp. (all are product names); bisphenol A novolac-type epoxy resins such as jER157S (product name) manufactured by Mitsubishi Chemical Corporation; tetraphenylol ethane-type epoxy resins such as jERYL-931 (product name) manufactured by Mitsubishi Chemical Corporation; heterocyclic epoxy resins such as TEPIC (product name) manufactured by Nissan Chemical Industries, Ltd.; diglycidyl phthalate resins such as BLEMMER DGT (product name) manufactured by NOF Corp.; tetraglycidyl xylenol ethane resins such as ZX-1063 (product name) manufactured by Tohto Kasei Co., Ltd.; naphthalene group-containing epoxy resins such as ESN-190 and ESN-360 manufactured by Nippon Steel & Sumikin Chemical Co., Ltd., and HP-4032, EXA-4750, and EXA-4700 manufactured by DIC Corp. (all are product names); epoxy resins having a dicyclopentadiene skeleton, such as HP-7200 and HP-7200H manufactured by DIC Corp. (all are product names); glycidyl methacrylate copolymer-based epoxy resins such as CP-50S and CP-50M manufactured by NOF Corp. (all are product names); cyclohexylmaleimide-glycidyl methacrylate copolymer epoxy resins; and epoxy-modified polybutadiene rubber derivatives (e.g., PB-3600 manufactured by Daicel Corp.) and CTBN-modified epoxy resins (e.g., YR-102 and YR-450 manufactured by Tohto Kasei Co., Ltd.).

These epoxy resins can be used alone or in combination of two or more thereof. Among them, a bisphenol-type epoxy resin, a phenol novolac-type epoxy resin, an amine-type epoxy resin, a novolac-type epoxy resin, a bixylenol-type epoxy resin, a biphenol-type epoxy resin, a biphenol novolac-type epoxy resin, or a mixture thereof is particularly preferred in view of working efficiency. A crystalline epoxy resin, which is in the form a liquid at 20° C. or has a melting temperature of 120° C. or less, having a viscosity of 1 Pa·s or less after being molten, is further preferred because the good working efficiency can be maintained even when the blending amount of resin filler is increased.

Examples of the polyfunctional oxetane compound include: polyfunctional oxetanes such as bis[(3-methyl-3-oxetanylmethoxy)methyl]ether, bis[(3-ethyl-3-oxetanylmethoxy)methyl] ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, and oligomers or copolymers thereof; and etherified products of oxetane alcohol and a hydroxy group-containing resin such as novolac resins, poly(p-hydroxystyrene), cardo-type bisphenols, calixarenes, calixresorcinarenes, or silsesquioxane. Other examples of the compound include copolymers of an unsaturated monomer having an oxetane ring and alkyl (meth)acrylate.

Examples of the compound having a plurality of cyclic thioether groups in the molecule include a bisphenol A-type episulfide resin YL7000 manufactured by Mitsubishi Chemical Corporation. Other examples of the above-mentioned compound include episulfide resins derived from novolac-type epoxy resins obtained by replacing the oxygen atom in the epoxy group with a sulfur atom.

The content of such a thermosetting resin having a plurality of cyclic (thio)ether groups in the molecule is preferably 20 to 80% by mass, more preferably 20 to 60% by mass, with respect to the total solid content of the resin composition of the present invention.

It is possible to add conventionally used various types of curing agents or curing accelerators, as a curing component for the thermosetting resin, to the composition of the present invention containing the thermosetting resin having a plurality of cyclic (thio)ether groups in the molecule. Examples of these are phenolic resins, acid-containing resins, imidazole compounds, acid anhydrides, aliphatic amines, alicyclic polyamines, aromatic polyamines, tertiary amines, dicyandiamide, guanidines, or epoxy adducts of these or microencapsulated ones thereof, organic phosphine compounds such as triphenylphosphine, tetraphenylphosphonium, and tetraphenyl borate, DBU or derivatives thereof. These materials can be used alone or in combination of two or more thereof, regardless of the kind of curing agent or curing accelerator.

The curing agent or the curing accelerator is preferably contained at a ratio of 0.5 to 100 parts by mass to 100 parts by mass of the thermosetting resin. When the content of the curing agent or the curing accelerator falls within this range, an adequate curing accelerating effect is obtained, as well as excellent properties such as adhesion, heat resistance, and mechanical strength of a cured product.

Among the curing agents described above, phenolic resins, imidazole compounds, and acid-containing compounds are preferred. Conventionally used phenolic resins such as phenol novolac resins, alkylphenol novolac resins, bisphenol A novolac resins, dicyclopentadiene-type phenolic resins, Xylok-type phenolic resins, terpene-modified phenolic resins, cresol/naphthol resins, and polyvinylphenols can be used alone or in combination of two or more thereof.

The imidazole compounds are preferable because of: the gentle reaction in a temperature range (80° C. to 130° C.) where a solvent in the composition is dried off; sufficient reaction carried out in a curing temperature range (150° C. to 200° C.), and physical properties to be satisfactory attained as the cured product. The imidazole compounds are also preferred in view of excellent adhesion to a copper circuit and copper foil. Specific examples of particularly preferred imidazole compounds include 2-ethyl-4-methylimidazole, 2-methylimidazole, 2-phenylimidazole, 2-phenyl-4-methylimidazole, bis(2-ethyl-4-methyl-imidazole), 2-phenyl-4-methyl-5-hydroxymethylimidazole, 2-phenyl-4,5-dihydroxymethylimidazole, and triazine-added imidazole. These imidazole compounds can be used alone or in combination of two or more thereof.

Any polymerizable compound having an acidic group can be used as an acid-containing compound. Examples of the compound which can be preferably used include: carboxylic acid compounds and carboxylic anhydrides; and acrylic resins including acrylic acid, acrylic acid esters, methyl acrylate, ethyl acrylate, n-butyl acrylate, acrylonitrile, acrylamide, methacrylic acid, methacrylic acid esters, methyl methacrylate, ethyl methacrylate, n-butyl methacrylate, methacrylamide, methacrylonitrile, and derivatives of these. Among others, preferred examples of the acrylic resins include styrene acrylic resins such as Joncryl® resin manufactured by BASF SE.

The resin filler as a component of the resin composition for a permanent insulating film of the present invention interacts with the compound containing at least one of a sulfur atom and a nitrogen atom and contributes to improve the performance of the interlaminar insulation layer or a permanent insulating film (e.g., a plating resist), for example, low permittivity or plating deposit elimination performance. Particularly, the deposit elimination performance is effectively applied not only for electroless plating but also for electrolytic plating.

Examples of such resin filler include those made of resins such as urethane resins, silicon resins, acrylic resins, styrene resins, fluorinated resins, phenolic resins, vinyl resins, and imide resins. Particularly, for plating deposit elimination performance (plating resistance) as a plating resist, a filler made of a hydrophobic resin (e.g., fluorinated resins, urethane resins, and silicon resins) is preferred, and a filler made of a fluorinated resin is more preferred also from the viewpoint of excellent low permittivity.

The fluorinated resin can be any resin containing a fluorine atom in the molecule without particular limitation. Specific examples of the resin include polytetrafluoroethylene (PTFE) and modified products thereof, tetrafluoroethylene-perfluoroalkyl vinyl ether copolymers (PFA), tetrafluoroethylene-ethylene copolymers (ETFE), tetrafluoroethylene-hexafluoropropylene copolymers (FEP), tetrafluoroethylene-vinylidene fluoride copolymers (TFE/VdF), tetrafluoroethylene-hexafluoropropylene-perfluoroalkyl vinyl ether copolymers (EPA), polychlorotrifluoroethylene (PCTFE), chlorotrifluoroethylene-ethylene copolymers (ECTFE), chlorotrifluoroethylene-vinylidene fluoride copolymers (CTFE/VdF), polyvinylidene fluoride (PVdF), and polyvinyl fluoride (PVF). Among them, PTFE, PFA, or a mixture thereof is preferred from the viewpoint of abrasion resistance and heat resistance. Specific examples of the fluorinated resin filler include Dyneon TF Micropowder TF9201Z, TF9207Z, and TF9205 (all are product names) manufactured by 3M Japan Ltd., POLYFLON PTFE F-104, F-106, F-108, F-201, F-205, F-208, F-302, and F-303 (all are product names) and Lubron L-5, L-2, and L-5F (all are product names) manufactured by Daikin Industries, Ltd., and TEFLON PTFE TLP-10F-1 (product name) manufactured by Du Pont-Mitsui Fluorochemicals Co., Ltd.

Examples of the silicon resin filler include silicon composite powders KMP-600, 601, 605, and X52-7030 (all are product names), silicon rubber powders KMP-597, 598, and 594, and silicon resin powders KMP-590, 701, X-52-854, and X-52-1621 (all are product names) manufactured by Shin-Etsu Chemical Co., Ltd.

Examples of the urethane resin filler include Art-pearl AK-400TR, AR-800T, C-400, C-600, C-800, P-400T, P-800T, JB-800T, JB-600T, JB-400T, U-600T, CE-400T, CE-800T, HI-400T, HI-400BK, HI-400W, MM-120T, MM-120TW, MM-101SW, TK-600T, and BP-800T (all are product names) manufactured by Negami Chemical Industrial Co., Ltd., and Dynamic Beads UCN-8070CM, UCN-8150CM, UCN-5070D, and UCN-5150D (all are product names) manufactured by Dainichiseika Color & Chemicals Mfg. Co., Ltd.

The average particle size of the resin filler is 0.1 to 30 μm, more preferably 0.1 to 15 μm. The shape of this resin filler is not limited and is more preferably of a spherical shape which can be highly filled without impairing hydrophobicity and the flowability of the composition. The content of the resin filler is preferably 10 to 80% by mass, more preferably 20 to 60% by mass, with respect to the total solid content of the resin composition. Within this range, better plating deposit eliminating properties can be exerted without impairing properties, such as adhesion to a base material and low permittivity, as a permanent insulating film.

The compound containing at least one of a sulfur atom and a nitrogen atom as a component of the resin composition for a permanent insulating film of the present invention serves as a negative catalyst for electroless plating. Such a compound may be an organic compound or an inorganic compound, and an organic compound is preferably used. Examples of the compound include thiols, sulfide compounds, thiocyanates, thiourea derivatives, sulfamic acid or salts thereof, amine compounds, amidines, ureas, amino acids, and heterocychlic compounds containing at least one of a sulfur atom and a nitrogen atom in the molecule. Of these, a heterocyclic compound containing at least one of a sulfur atom and a nitrogen atom in the molecule, an aliphatic thiol, and a disulfide compound are preferred.

<Heterocyclic Compound Containing at Least One of Sulfur Atom and Nitrogen Atom in the Molecule>

Examples of the heterocychlic compound containing at least one of a sulfur atom and a nitrogen atom in the molecule include pyrroles, pyrrolines, pyrrolidines, pyrazoles, pyrazolines, pyrazolidines, imidazoles, imidazolines, triazoles, tetrazoles, pyridines, piperidines, pyridazines, pyrimidines, pyrazines, piperazines, triazines, tetrazines, indoles, isoindoles, indazoles, purines, norharmans, perimidines, quinolines, isoquinolines, shinorines, quinoxalines, quinazolines, naphthyridines, pteridines, carbazoles, acridines, phenazines, phenanthridines, phenanthrolines, trithianes, thiophenes, benzothiophenes, isobenzothiophenes, dithiins, thianthrenes, thienothiophenes, oxazoles, isoxazoles, oxadiazoles, oxazines, morpholines, thiazoles, isothiazoles, thiadiazoles, thiazines, and phenothiazines.

Among them, imidazoles, pyrazoles, triazoles, triazines, thiazoles, and thiadiazoles are preferred as heterocyclic compounds, and these compounds may have an amino group, a carboxyl group, a cyano group, or a mercapto group.

More specific examples of these include, but are not limited to: imidazoles such as imidazole, 2-methylimidazole, 2-ethyl-4-methylimidazole, 2-mercaptoimidazole, 2-mercaptobenzimidazole, 5-amino-2-mercaptobenzimidazole, 2-mercaptomethylbenzimidazole, 2-ethylimidazole-4-dithiocarboxylic acid, 2-methylimidazole-4-carboxylic acid, 1-(2-aminoethyl)-2-methylimidazole, 1-(2-cyanoethyl)-2-methylimidazole, 2-phenyl-4,5-dihydroxymethylimidazole, benzimidazole, and 2-ethyl-4-thiocarbamoylimidazole; pyrazoles such as pyrazole, 4-amino-6-mercaptopyrazole, and 3-amino-4-cyano-pyrazole; triazoles such as 1,2,4-triazole, 2-amino-1,2,4-triazole, 1,2-diamino-1,2,4-triazole, 1-mercapto-1,2,4-triazole, and 3-amino-5-mercapto-1,2,4-triazole; triazines such as 2-aminotriazine, 2,4-diamino-6-(6-(2-(2-methyl-1-imidazolyl)ethyl)triazine, 2,4,6-trimercapto-s-triazine-trisodium salt, 1,3,5-tris(3-mercaptobutyryloxyethyl)-1,3,5-triazine-2,4,6(1H,3H,5H)-trione, and 1,3,5-triazine-2,4,6-triamine; thiazoles such as 2-aminothiazole, benzothiazole, 2-methylbenzothiazole, 2-mercaptobenzothiazole, 2-mercaptobenzothiazole zinc salt, di-2-benzothiazolyl disulfide, N-cyclohexylbenzothiazole, N-cyclohexyl-2-benzothiazole sulfenamide, N-oxydiethylene-2-benzothiazole sulfenamide, N-tert-butyl-2-benzothiazole sulfenamide, 2-(4′-morpholinodithio)benzothiazole, N,N-dicyclohexyl-2-benzothiazole sulfenamide, and N-tert-butyl-2-benzothiazolyl sulfenamide; and thiadiazoles such as 1,3,4-thiadiazole, 2-amino-1,3,4-thiadiazole, and 2-amino-5-mercapto-1,3,4-thiadiazole.

These heterocyclic compounds each containing at least one of a sulfur atom and a nitrogen atom in the molecule may be used alone or in combination of two or more of these.

<Aliphatic Thiol or Disulfide Compound>

Examples of the aliphatic thiol include compounds represented by the following general formulas (1) to (3), and compounds containing a group represented by the following formula (4):

HS—(CH₂)a-COOH (1)

wherein a represents an integer of 1 or larger, preferably in the range of 1 to 20,

HS—(CH₂)b-OH (2)

wherein b represents an integer of 5 or larger, preferably in the range 5 to 30,

HS—(CH₂)c-NH₂ (3)

wherein c represents an integer of 5 or larger, preferably in the range 5 to 30, and

HS—R1-CO— (4)

wherein R1 represents a divalent linear hydrocarbon group having 1 to 22 carbon atoms, for example, an alkylene group, or a branched hydrocarbon group, for example, —CH(R1)-CH₂— (R1 represents a monovalent hydrocarbon group having 1 to 20 carbon atoms), preferably an alkylene group.

In the present invention, a compound having 1 to 4 groups represented by the formula (4), particularly, a compound having 2 to 4 groups represented by the formula (4), is preferably used. Specific examples thereof can include mercaptocarboxylic acid esters of linear or branched monohydric to tetrahydric alcohols, for example, methyl-3-mercaptopropionate, 2-ethylhexyl-3-mercaptopropionate, n-octyl-3-mercaptopropionate, methoxybutyl-3-mercaptopropionate, stearyl-3-mercaptopropionate, tetraethylene glycol bis(3-mercaptopropionate), trimethylolpropanetris(3-mercaptopropionate), pentaerythritol tetrakis(3-mercaptopropionate), and pentaerythritol tetrakis(3-mercaptobutyrate).

Examples of the disulfide compound include a compound represented by the following general formula (5):

R2-(CH₂)n-(R4)p-S—S—(R5)q-(CH₂)m-R3 (5)

wherein R2 and R3 each independently represent a hydroxyl group, a carboxyl group, or an amino group, R4 and R5 each independently represent a divalent organic group having a hydroxyl group, a carboxyl group, or an amino group, m and n each independently represent an integer of 4 or larger, preferably 4 to 10, and p and q each independently represent 0 or 1.

The content of such a compound containing at least one of a sulfur atom and a nitrogen atom is 0.1 to 50 parts by mass, more preferably 1 to 30 parts by mass, with respect to 100 parts by mass of the thermosetting resin components including a curing agent or a curing accelerator. Within this range, the resulting permanent insulating film (plating resist) can exert better plating deposit elimination performance, without having plating inhibition at a plating portion due to the elution of the compound.

The resin composition for a permanent insulating film of the present invention as described above may optionally further contain an inorganic filler, a solvent, a diluent, a thickener, an antifoaming agent, a leveling agent, a coupling agent, a frame retardant, and a photopolymerization initiator.

The printed wiring board of the present invention and a method for producing the same will be described below.

The printed wiring board of the present invention is characterized by having a plating resist portion, which is made of a cured product from the above-discussed resin composition for a permanent insulating film of the present invention. Particularly in a multilayer printed wiring board in which conductive layers having a circuit pattern and insulation layers are alternately overlaid with each other, as a laminate, a through-hole is formed in the laminate, enabling electrical conductivity among conductive layers. In addition, the plating resist portion, which is made of a cured product of the resin composition for a permanent insulating film of the present invention, is provided on at least one of interlaminar parts including an interlaminar part between a conductive layer and an insulation layer and an interlaminar part between insulation layers.

In such a multilayer printed wiring board, conductive layers and insulation layers are alternately overlaid with each other. Each conductive layer is structured, having a conductor circuit having a circuit pattern, which is provided on an insulation layer. In other words, a wire circuit, which configures the conductive layer, and the insulation material, which is not a part of the conductive layer and embedded into spaces of the circuit pattern are provided in a layer including a conductive layer having a circuit pattern contains. Therefore, both interlaminar parts, i.e., an interlaminar part between the conductive layer and the insulation layer and another interlaminar part between the insulation layers are exposed, as exposed parts, in the circumference of the opening as the through-hole. The plating resist portion is generally provided on both the interlaminar parts. Alternatively, it is possible to provide the plate resist portion only on the interlaminar part between a conductive layer and an insulation layer or only on the interlaminar part between the insulation layers.

The process for producing the multilayer printed wiring board according to the present invention comprise:

a step of preparing a multilayered structure by hot-pressing wiring boards, for instance via epoxy prepreg (insulation layer), each wiring board having the insulation layer (including a substrate) having a conductive layer with a circuit pattern (conductor circuit), the wiring boards including a plating resist portion at a predetermined position (s) (on either a conductive layer or an insulation layer, or both), which have been prepared by applying the resin composition for a permanent insulating film of the present invention, and curing the same; a step of forming an opening as a through-hole in the multilayered wiring board with a drill or laser so as to penetrate the plating resist portion;

a step of performing a desmear treatment; and

a step of performing a plating treatment.

(Hot Press)

The hot press can be performed by use of a known method. The press conditions are preferably 20 to 60 Kg/cm² at 150 to 200° C.

(Desmear Treatment)

The desmear treatment can be performed by a known method. The process can be performed, for example, using an oxidizing agent composed of an aqueous solution of chromic acid, permanganate, or the like, and may be performed with oxygen plasma, mixed plasma of CF₄ and oxygen, corona discharge, or the like.

(Plating Treatment)

In the multilayer printed wiring board of the present invention, a portion other than the plating resist in the opening as a through-hole is coated with a conductive substance by the plating treatment. This plating treatment is performed by electroless plating. If desired, electrolytic plating can be further performed, subsequently. Examples of a catalyst for the electroless plating include palladium, tin, silver, gold, platinum, copper, and nickel, and combinations thereof. Palladium is preferred. Examples of the electroless plating include electroless copper plating, electroless nickel plating, electroless nickel-tungsten alloy plating, electroless tin plating, and electroless gold plating. Electroless copper plating is preferred.

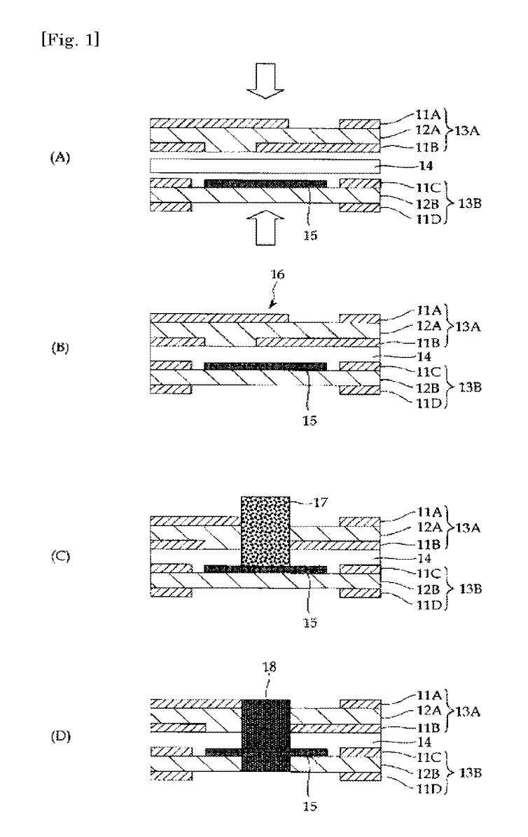

Exemplary embodiments will be described with reference to FIGS. 1, 2, and 3, which are regarding the production of a multilayer printed wiring board having partial through-holes by use of the resin composition for a permanent insulating film of the present invention. These figures show cross-sections where conductive layers having a circuit pattern (i.e., wired portions) and insulation layers are alternately overlaid with each other. In this context, the film thickness of the plating resist portion is generally 10 to 200 μm, preferably 50 to 100 μm.

As shown in FIG. 1(A), a wiring board 13A, which has two conductive layers having circuit patterns (11A and 11B, respectively) and an insulation layer 12A provided therebetween, and another wiring board 13B, which has two conductive layers having circuit patterns (11C and 11D, respectively) and an insulation layer 12B therebetween are superimposed with each other. In this embodiment, the resin composition for a permanent insulating film of the present invention, is applied only on the insulation layer 12B, and cured, to prepare the wiring board 13B having the plating resist portion 15. In this state, the wiring boards 13A and 13B are hot-pressed via a prepreg 14 to prepare a multilayer printed wiring board 16 as shown in FIG. 1(B). This prepreg 14 has the function of insulating conductive layers and therefore corresponds to an insulation layer constituting the printed wiring board of the present invention.

Subsequently, as shown in FIG. 1(C), an opening as a through-hole is prepared by use of a drill 17 (penetration by use of the drill 17). Then, a desmear process and following electroless/electrolytic copper plating are performed to form a through-hole 18 as shown in FIG. 1(D). Herein, the plating resist portion 15 prepared by curing the resin composition for a permanent insulating film of the present invention is not plated. Therefore, the through-hole is partitioned at this site so that partial through-holes can be formed. The partial (plated) through-holes are through-holes resulting from the physical partitioning of the through-hole by the plating resist portion present in the through-hole. The partial through-holes thus formed can minimize the adverse effect (stub effect), which would be made by the provision of an unnecessary conductor portion in the through-hole on signals.

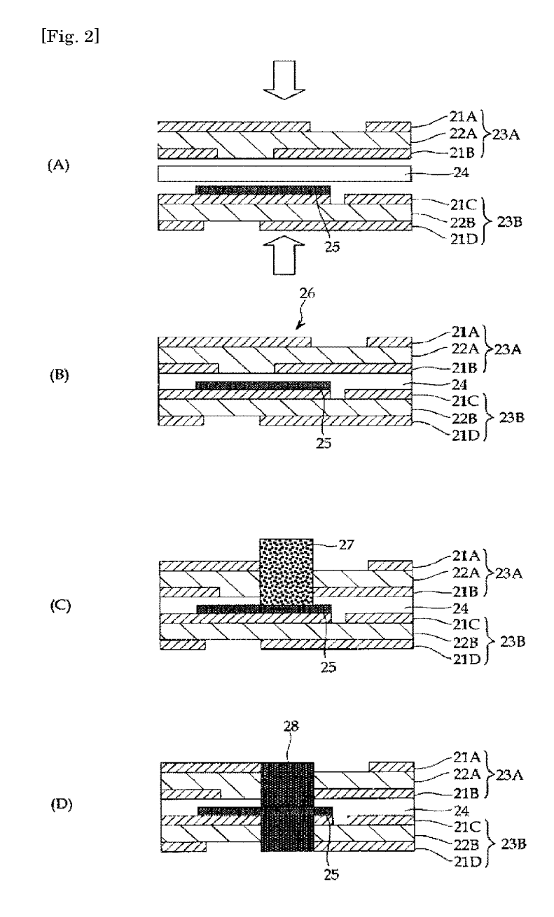

As shown in FIG. 2(A), a substrate 23A, which has two conductive layers having circuit patterns (21A and 21B, respectively) and an insulation layer 22A therebetween, and another substrate 23B, which has two conductive layers having circuit patterns (21C and 21D, respectively) and an insulation layer 22B therebetween are laminated with each other. In this embodiment, the resin composition for a permanent insulating film of the present invention, is applied only on the conductive layer 21C, and cured, to prepare the substrate 23B having the plating resist portion 25. In this state, the substrates 23A and 23B are hot-pressed via a prepreg 24 to prepare a multilayer printed wiring board 26 as shown in FIG. 2(B).

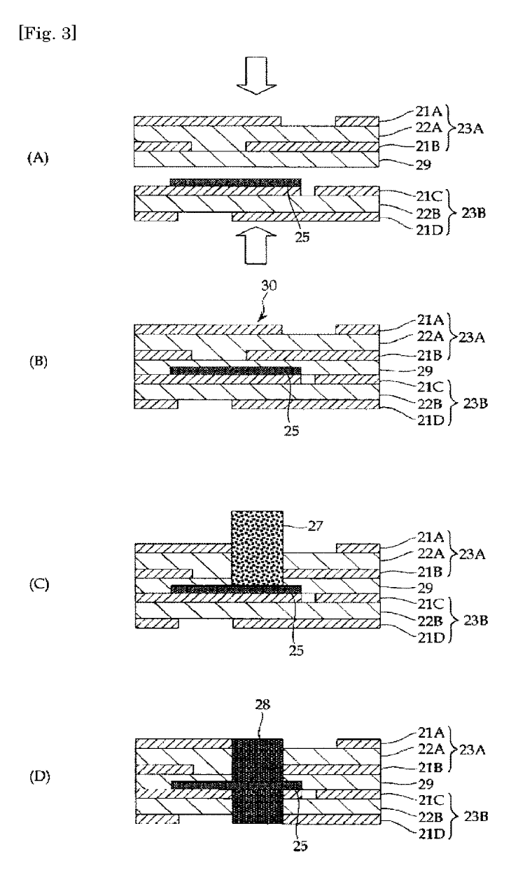

Alternatively, as shown in FIG. 3, an insulation layer 29 is further provided on the surface of the conductive layer 21B in the substrate 23A. The insulation layer 29 is provided so as to oppose the plating resist portion 25 on the substrate 23B. These two substrates may be hot-pressed without the provision of the prepreg 24.

Subsequently, as shown in FIG. 2(C), an opening as a through-hole is prepared by use of a drill 27 (penetration by use of the drill 27). Then, a desmear treatment and subsequent electroless/electrolytic copper plating are performed to form a through-hole 28 as shown in FIG. 2(D). Herein, the plating resist portion 25 prepared by curing the resin composition for a permanent insulating film of the present invention is not plated. Therefore, the through-hole is partitioned at this site so that partial through-holes can be formed. The partial (plated) through-holes are through-holes resulting from the physical partitioning of the through-hole by the plating resist portion present in the through-hole. The partial through-holes thus formed can minimize the adverse effect (stub effect), which would be made by the provision of an unnecessary conductor portion in the through-hole on signals. In addition to the above, partial through-holes allow a desired region (portion for which electric signal transmission is necessary) to be plated easily and precisely. The above explanation applies to the embodiment described in FIGS. 3(C) and 3(D).

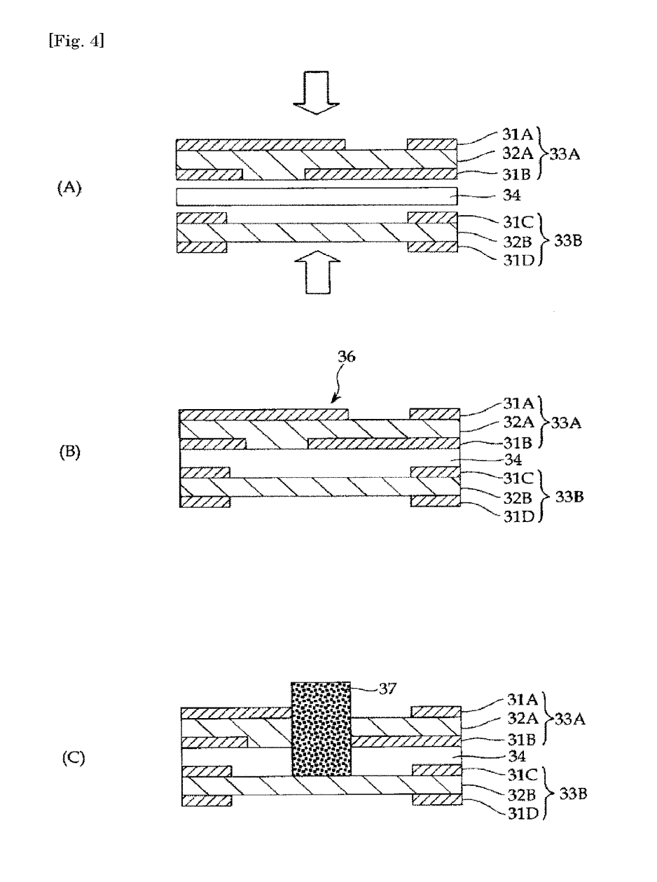

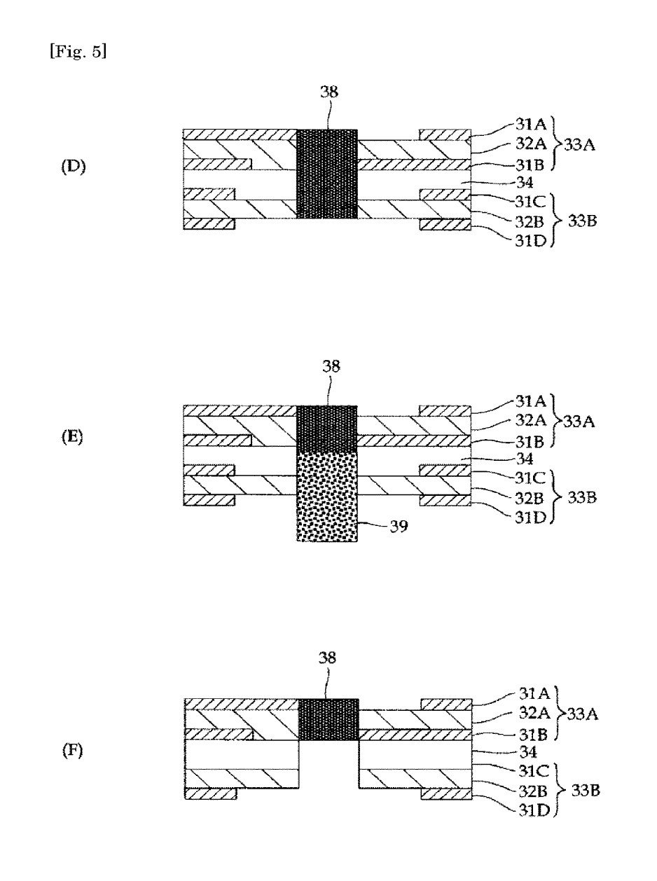

By contrast, FIG. 4(A) shows a conventional way, wherein substrates, without the application of the resin composition for a permanent insulating film of the present invention thereto, are subjected to hot-press, via prepreg 34a provided between the substrates. (Herein, the substrates are: a substrate 33A having two conductive layers 31A and 31B with circuit patterns and an insulation layer 32A provided therebetween, and a substrate 33B having two conductive layers 31C and 31D having circuit patterns and an insulation layer 32B provided therebetween.) Accordingly, a conventional multilayer printed wiring board 36 shown in FIG. 4(B) is prepared. Subsequently, as shown in FIG. 4(C), an opening as a through-hole is prepared by use of a drill 37 (penetration by use of the drill 37). After desmear treatment, electroless/electrolytic copper plating are performed for entirely plating the opening as a through-hole to provide a through-hole 38, as shown in FIG. 5(D). In such a case, wirings can be largely reduced, and the process step(s) is/are simplified. Therefore, the man-hour can be decreased. On the other hand, it is difficult to attain the interlayer connection only for a predetermined part in layers adjacent to each other. Therefore, it is necessary, for blocking a signal(s) from an unnecessary conductor portion(s) present in the through-hole (i.e., for preventing the stub effect), to remove the unnecessary conductor portion(s) by use of a back drill 39, as shown in FIG. 5(E). FIG. 5(F) is a cross-sectional view of the printed wiring board after the removal of the unnecessary conductor portion with the back drill.

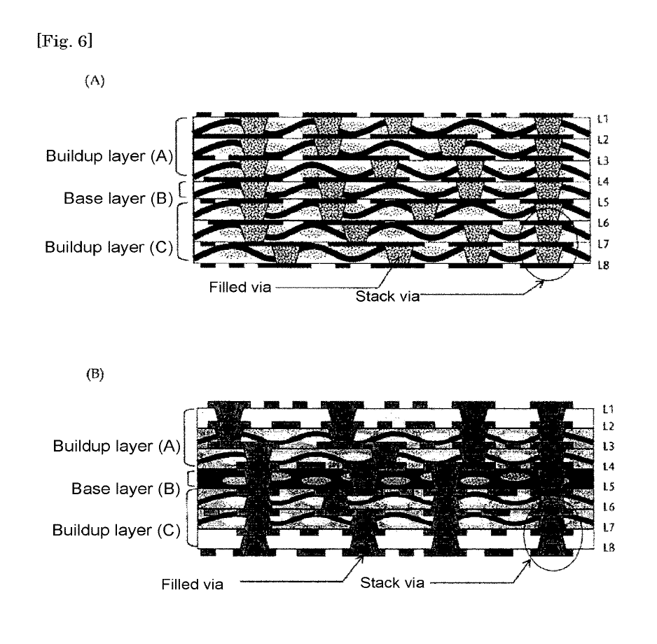

As shown in FIGS. 6(A) and 6(B), a multilayer printed wiring board can be prepared by a “buildup method” wherein each layer is subjected lamination, a hole drilling process, a wiring process, or the like, in turn. In such a case, the process step(s) will be complicated, requiring a large amount of man-hour, while it is possible to attain the interlayer connection only for a predetermined part in layers adjacent to each other.

Hereinafter, components constituting the multilayer printed wiring board of the present invention will be specifically described.

<Through-Hole>

The multilayer printed wiring board of the present invention has an opening as a through-hole (through-hole before plating treatment), which penetrates the plating resist portion provided on a conductive layer having a circuit pattern and/or an insulation layer. Thus, the plating resist portion is formed at an interlaminar part between a conductive layer and an insulation layer and/or an interlaminar part between insulation layers. The opening as a through-hole is subjected to the plating treatment to provide a plated through-hole. As described above, partial through-holes are through-holes resulting from physically partitioning the through-hole by the plating resist portion.

In the process for providing the plating resist portion on a conductive layer having a circuit pattern, the coating film is formed by coating or printing the resin composition for a permanent insulating film of the present invention at a predetermined site on the conductive layer, and heat-curing the resin composition. The same procedures are taken also for preparation on the insulation layer. A roll coater method, a spray method, or the like can be used as an application method, and a screen printing method, a gravure printing method, or the like can be used as a printing method. The heat curing is performed at generally 80 to 200° C., preferably 100 to 170° C., for 5 to 60 minutes, preferably 10 to 60 minutes.

<Conductive Layer Having Circuit Pattern>

Each conductive layer in the multilayer printed wiring board of the present invention is a patterned conductor circuit formed from a conductive material such as copper, nickel, tin, gold, or an alloy of these.

Any known method can be used for forming the conductor circuit.

Examples of the method include a subtractive method and an additive method.

<Insulation Layer>

Each insulation layer, which is provided between conductive layers having a circuit pattern in the multilayer printed wiring board of the present invention, can be prepared from any materials used for insulation layers of a multilayer printed wiring boards. The insulation layer is preferably prepared by curing a resin composition. The resin composition may be in a liquid state or may be in a sheet form.

As mentioned above, the prepreg is also regarded as the insulation layers as a constituent of the multilayer printed wiring board of the present invention, since the prepreg has an insulating function for the conductive layers.

The prepreg generally has a sheet shape, prepared by impregnating a base material such as a glass cloth with a varnish such as an epoxy resin composition, a bismaleimide-triazine resin composition, or a polyimide resin composition and then semi-curing the varnish by heating and drying. Examples includes R-1410A, R-5670(K), R-1650D, and R-1551 manufactured by Panasonic Electric Works Co., Ltd., GEPL-190 and GHPL-830 manufactured by Mitsubishi Gas Chemical Co., Inc., and MCL-E-67 and MCL-I-671 manufactured by Hitachi Chemical Co., Ltd.

<Core Substrate>

The multilayer printed wiring board of the present invention may have a core substrate. The core substrate serves, in the multilayer printed wiring board, as a base for forming conductive layers having circuit patterns and interlaminar insulation layers thereon. Namely, the core substrate plays a role of a core material. Examples of the material to be used for the core substrate include glass epoxy materials obtained by impregnating a glass cloth or the like with a thermosetting resin such as an epoxy resin followed by curing; ceramics; and metal core substrates.

### EXAMPLES

Hereinafter, the present invention will be described in more detail with reference to the Examples. The present invention is not limited by the Examples below.

### Examples 1 to 8 and Comparative Examples 1 to 3

### Preparation of Resin Composition for Permanent Insulating Film

The components for the resin composition, as shown in Table 1 below, were kneaded by using a three-roll mill to obtain resin compositions of Examples 1 to 8 and Comparative Examples 1 to 3. The numbers in the table are based on parts by mass.

TABLE 1

| | | | | | | | | | | Comp. | Comp. | Comp. |
|---|---|---|---|---|---|---|---|---|---|---|---|---|
| | | Ex. 1 | Ex. 2 | Ex. 3 | Ex. 4 | Ex. 5 | Ex. 6 | Ex. 7 | Ex. 8 | Ex. 1 | Ex. 2 | Ex. 3 |
| Thermosetting | Bisphenol A-type | 90 | | 90 | 90 | 60 | 60 | 90 | 90 | 90 | 90 | 90 |
| resin | epoxy resin *1 | | | | | | | | | | | |
| | Novolac-type | | 100 | | | | | | | | | |
| | epoxy resin | | | | | | | | | | | |
| | solution *2 | | | | | | | | | | | |
| Curing | 2-Phenylimidazole | 5 | | 3 | 5 | | | 4 | 5 | 5 | 5 | |
| agent/curing | 2-Ethyl-4- | | 5 | | | | | | | | | |
| accelerator | methylimidazole | | | | | | | | | | | |
| | Dicyandiamide | | | | | 0.5 | | | | | | 0.05 |
| | Phenol novolac | | | | | 50 | | | | | | |
| | resin solution *3 | | | | | | | | | | | |
| | Acrylic acid resin | | | | | | 80 | | | | | |
| | solution *4 | | | | | | | | | | | |
| Filler | Fluororesin- | 30 | | 30 | | 30 | 50 | 20 | 30 | | | |
| | based filler A *5 | | | | | | | | | | | |
| | Fluororesin- | | 30 | | | | | 10 | | | | |
| | based filler B *6 | | | | | | | | | | | |
| | Silicone | | | | 50 | | | | | | | |
| | resin-based filler | | | | | | | | | | | |
| | *7 | | | | | | | | | | | |
| | Silica *8 | | | | | | | | 10 | | 50 | |
| Compound | Triazine | 3 | | | 5 | 3 | | 2 | 3 | 3 | | |
| containing at | compound *9 | | | | | | | | | | | |
| least one of | Thiazole | | 3 | | | | | 2 | | | | |
| sulfur atom | compound *10 | | | | | | | | | | | |
| and nitrogen | Aliphatic thiol | | | 3 | 3 | | 5 | | | | | |
| atom | compound *11 | | | | | | | | | | | |

| | | | | | | | | | | | |
|---|---|---|---|---|---|---|---|---|---|---|---|
| Plating resist performance | ∘ | ∘ | ∘ | ∘ | ∘ | ∘ | ∘ | ∘ | Δ | × | × |
| Permittivity | ∘ | ∘ | ∘ | Δ | Δ | ∘ | ∘ | ∘ | Δ | Δ | Δ |
| Adhesion | ∘ | ∘ | ∘ | ∘ | ∘ | ∘ | ∘ | ∘ | ∘ | ∘ | ∘ |

*1 jER828 manufactured by Mitsubishi Chemical Corporation.
*2 90% carbitol acetate solution of DEN438 manufactured by The Dow Chemical Company
*3 60% carbitol acetate solution of HF-1M manufactured by Meiwa Plastic Industries Ltd.
*4 40% carbitol solution of styrene-acrylic resin Joncryl 678 manufactured by BASF SE (molecular weight: 8500, acid value: 215 mg/gKOH)
*5 Lubron L-5 manufactured by Daikin Industries, Ltd. (average particle size: 5 μm)
*6 TF-9205 manufactured by 3M Japan Ltd. (average particle size: 8 μm)
*7 KMP-590 manufactured by Shin-Etsu Chemical Co., Ltd. (average particle size: 2 μm)
*8 Spherical silica ADMA C5 manufactured by Admatechs Co., Ltd. (average particle size: 1.6 μm)
*9 2,4-Diamino-6-methacryloyloxyethyl-s-triazine
*10 2-Mercaptobenzothiazole
*11 Pentaerythritol tetrakis(3-mercaptobutyrate)

(Preparation of Test Substrate)

The resin compositions of Examples 1 to 8 and Comparative Examples 1 to 3 were applied to the full surfaces of copper-plane FR-4 substrates, respectively, by screen printing, so as to have a film thickness, after drying, of approximately 50 μm. Each of the resultant films was cured by heating at 170° C. for 60 minutes in a hot-air circulation dryer. Subsequently, the thus cured substrate having the plating resist and another copper-plane FR-4 substrate were laminated by hot press at 170° C. for 60 minutes at a pressure of 20 kg/cm² via an epoxy prepreg (R-1650D manufactured by Panasonic Electric Works Co., Ltd.). Then, the laminate was drilled to form an opening as a through-hole therein, having a hole diameter of 0.7 mm. Thus, test substrates of Examples 1 to 8 and Comparative Examples 1 to 3 were prepared.

(Desmear Treatment)

The test substrates of Examples 1 to 8 and Comparative Examples 1 to 3 were dipped/immersed in a swelling solution consisting of a mixed solution of Swelling Dip Securiganth P (manufactured by Atotech Japan K.K., 500 ml/l) and 48% sodium hydroxide (4.1 ml/l) at 60° C. for 5 minutes. Thereafter, the test substrates were dipped in a roughening solution as a mixed solution of Concentrate Compact CP (manufactured by Atotech Japan K.K., 600 ml/l) and 48% sodium hydroxide (55.3 ml/l) at 80° C. for 20 minutes. Finally, each test substrate was dipped in a neutralizing solution containing Reduction Securiganth P500 (manufactured by Atotech Japan K.K., 100 ml/l) and 96% sulfuric acid (46.9 ml/l) at 40° C. for 5 minutes.

(Electroless Copper Plating Treatment)

After the desmear treatment, each test substrate was dipped in MCD-PL (manufactured by UYEMURA Co., Ltd., 50 ml/l) at 40° C. for 5 minutes (cleaner/conditioner step), subsequently dipped in a mixed solution of MDP-2 (manufactured by UYEMURA Co., Ltd., 8 ml/l) and 96% sulfuric acid (0.81 ml/l) at 25° C. for 2 minutes (predip step), subsequently dipped in a mixed solution of MAT-SP (manufactured by UYEMURA Co., Ltd., 50 ml/l) and 1 N sodium hydroxide (40 ml/l) at 40° C. for 5 minutes (catalyst addition step), subsequently dipped in a mixed solution of MRD-2-C (manufactured by UYEMURA Co., Ltd., 10 ml/l), MAB-4-C (manufactured by UYEMURA Co., Ltd., 50 ml/l), and MAB-4-A (manufactured by UYEMURA Co., Ltd., 10 ml/l) at 35° C. for 3 minutes (reduction step), then dipped in MEL-3-A (manufactured by UYEMURA Co., Ltd., 50 ml/l) at 25° C. for 1 minute (accelerator step), and finally dipped in a mixed solution of PEA-6-A (manufactured by UYEMURA Co., Ltd., 100 ml/l), PEA-6-B (manufactured by UYEMURA Co., Ltd., 50 ml/l), PEA-6-C (manufactured by UYEMURA Co., Ltd., 14 ml/l), PEA-6-D (manufactured by UYEMURA Co., Ltd., 12 ml/l), PEA-6-E (manufactured by UYEMURA Co., Ltd., 50 ml/l), and a 37% aqueous formaldehyde solution (5 ml/l) at 36° C. for 20 minutes (electroless copper plating step). Then, each test substrate was dried at 150° C. for 30 minutes in a hot-air circulation dryer so that an electroless copper plated coating film of approximately 1 μm was formed on the through-hole opening in the test substrate.

(Electrolytic Copper Plating Treatment)

After the formation of the electroless copper plated coating film, each test substrate was dipped in a mixed solution of Acid Cleaner FR (manufactured by Atotech Japan K.K., 100 ml/l) and 96% sulfuric acid (100 ml/l) at 23° C. for 1 minute (acid cleaner step). Subsequently, the substrate was dipped in 96% sulfuric acid (100 ml/l) at 23° C. for 1 minute (acid dipping step), and finally dipped in a mixed solution of copper(II) sulfate pentahydrate (60 g/l), 96% sulfuric acid (125 ml/l), sodium chloride (70 mg/l), a basic leveler CUPRACID HL (manufactured by Atotech Japan K.K., 20 ml/l), and a correcting agent CUPRACID GS (manufactured by Atotech Japan K.K., 0.2 ml/l) at 23° C. for 60 minutes (current density: 1 A/dm²) (copper sulfate electric plating step). Then, each test substrate was dried at 150° C. for 60 minutes in a hot-air circulation dryer. Accordingly, an electrolytic copper plated coating film of approximately 25 μm was prepared on the through-hole openings of the test substrates. Thus, partial through-holes were prepared.

[Plating Resist (Elimination) Performance]

(Evaluation Method)

The cross-sectional surface of the test substrate, having the partial through-holes prepared as mentioned above, was polished. The surface was the cross-sectional surface of the through-hole portion was observed by use of a microscope. The presence or absence of copper plating deposit to the plating resist portion (layer), which is made of the cured product of each of the resin compositions of Examples 1 to 8 and Comparative Examples 1 to 3, was observed. Evaluation was made, based on the criteria described below.

(Criteria)

∘: The plating resist portion in the through-hole was not plated with the conductive substance, whereas the portion free from the plating resist portion was plated with the conductive substance.

Δ: The plating resist portion in the through-hole was partially plated with the conductive substance.

x: The plating resist portion in the through-hole was plated with the conductive substance.

[Permittivity]

(Preparation of Evaluation Substrate)

The resin compositions of Examples 1 to 8 and Comparative Examples 1 to 3 were printed on the full surfaces of copper-plane FR-4 substrates, respectively, by screen printing, so as to have a film thickness, after drying, of approximately 50 μm. Each of the resultant films was cured by heating at 170° C. for 60 minutes in a hot-air circulation dryer. Subsequently, a silver-containing paste was applied in a circle pattern of 38 mm in diameter by screen printing on each plating resist thus cured. The silver-containing paste was cured by heating at 140° C. for 30 minutes to prepare evaluation substrates of Examples 1 to 8 and Comparative Examples 1 to 3.

(Evaluation Method)

The permittivity of each evaluation substrate thus prepared was measured at 1 MHz according to JISC6481 and evaluated according to the criteria given below. The evaluation results are also shown in Table 1.

(Criteria)

∘: Permittivity was 3.5 or lower.

Δ: Permittivity was larger than 3.5 and 5 or lower.

x: Permittivity was larger than 5.

[Adhesion]

(Preparation of Substrate for Evaluation)

The resin compositions of Examples 1 to 8 and Comparative Examples 1 to 3 were printed on full surfaces of copper-plane FR-4 substrates, respectively, by screen printing, so as to have a film thickness, after drying, of approximately 50 μm. Each of the resultant substrates was cured by heating at 170° C. for 60 minutes in a hot-air circulation dryer. Thus, substrates of Examples 1 to 8 and Comparative Examples 1 to 3 for evaluation were prepared.

(Evaluation Method)

The thus obtained substrate for evaluation was cross-cut by use of a cross cut guide. The delamination was evaluated by tape peeling. The evaluation results are also shown in Table 1.

(Criteria)

∘: The cured product was not delaminated.

Δ: Delamination was slightly observed at a cross-cut corner.

x: Delamination was observed at several parts.

As is evident from the results in Table 1, it was confirmed, by the Examples of the present invention, that the product of the invention had an excellent adhesion property to the substrate and also an excellent plating resist performance. It was also found that the use of the fluororesin-based filler contributed to lower the permittivity of the plating resist (permanent insulating film).

1: A resin composition for a permanent insulating film, comprising:
a thermosetting resin;
a resin filler; and
a compound comprising at least one atom selected from the group consisting of a sulfur atom and a nitrogen atom.

2: The resin composition according to claim 1, wherein the resin filler comprises a hydrophobic resin.

3: The resin composition according to claim 1, wherein the compound is at least one compound selected from the group consisting of a heterocyclic compound, an aliphatic thiol, and a disulfide compound.

4: A printed wiring board, comprising:
a laminate structure comprising a plurality of conductive layers having circuit patterns, a plurality of insulation layers laminated on the conductive layers, a through-hole formed through the conductive layers and insulation layers, and a plating resist portion comprising a cured product of the resin composition of claim 1, exposed in an opening of the through-hole and formed on at least one of an interlaminar part between one of the conductive layers and one of the insulation layers and an interlaminar part between the insulation layers.

5: A permanent insulating film comprising:
a cured product of the resin composition of claim 1.

6: A printed wiring board comprising:
a permanent insulating film comprising a cured product of the resin composition of claim 1.

7: A multilayer printed wiring board, comprising:
a plurality of conductive layers having circuit patterns;
a plurality of insulation layers alternately laminated on the conductive layers; and
a through-hole configured to connect electrical conductivity between the conductive layers and having a plating resist portion and a plating portion formed in part exposed from the plating resist portion,
wherein the plating resist portion comprises a cured product of the resin composition of claim 1 and is exposed in an opening of the through-hole and formed on at least one of an interlaminar part between one of the conductive layers and one of the insulation layers and an interlaminar part between the insulation layers.

8: The multilayer printed wiring board according to claim 7, wherein the plating portion of the through-hole is partitioned.

9: The multilayer printed wiring board according to claim 7, wherein the plating resist portion is formed on the insulation layer or insulating layers each comprising a prepreg.

10: A process for producing a multilayer printed wiring board, comprising:
preparing a laminate structure comprising a plurality of conductive layers, a plurality of insulation layers alternately laminated on the conductive layers, and a plating resist portion;
forming an opening for a through-hole in the laminate structure such that the opening penetrates through the plating resist portion, by a drill or a laser;
applying desmear treatment to the opening for a through-hole such that the desmeared opening obtained; and
applying plating treatment to the desmeared opening for a through-hole,
wherein the plurality of conductive layers has circuit patterns, the plating resist portion comprises a cured product of the resin composition of claim 1 and is exposed in an opening of the through-hole and formed on at least one of an interlaminar part between one of the conductive layers and one of the insulation layers and an interlaminar part between the insulation layers, and the preparing of the laminate structure comprises hot-pressing the conductive layers and the plating resist portion.

11: The multilayer printed wiring board according to claim 8, wherein the plating resist portion is formed on the insulation layer or insulating layers each comprising a prepreg.

12: The resin composition according to claim 2, wherein the compound is at least one compound selected from the group consisting of a heterocyclic compound, an aliphatic thiol, and a disulfide compound.

13: A printed wiring board, comprising:
a laminated structure comprising a plurality of conductive layers having circuit patterns, a plurality of insulation layers alternately laminated on the conductive layers, a through-hole formed through the conductive layers and insulation layers, and a plating resist portion comprising a cured product of the resin composition of claim 2, exposed in an opening of the through-hole and formed on at least one of an interlaminar part between one of the conductive layers and one of the insulation layers and an interlaminar part between the insulation layers.

14: A permanent insulating film comprising a cured product of the resin composition of claim 2.

15: A printed wiring board comprising a permanent insulating film comprising a cured product of the resin composition of claim 2.

16: A multilayer printed wiring board, comprising:
a plurality of conductive layers having circuit patterns;
a plurality of insulation layers alternately laminated on the conductive layers; and
a through-hole configured to connect electrical conductivity between the conductive layers and having a plating resist portion and a plating portion formed in a part exposed from the plating resist portion,
wherein the plating resist portion comprises a cured product of the resin composition of claim 2 and is exposed in an opening of the through-hole and formed on at least one of an interlaminar part between one of the conductive layers and one of the insulation layers and an interlaminar part between the insulation layers.

17: The multilayer printed wiring board according to claim 16, wherein the plating portion of the through-hole is partitioned.

18: The multilayer printed wiring board according to claim 16, wherein the plating resist portion is formed on the insulation layer or insulating layers each comprising a prepreg.

19: The multilayer printed wiring board according to claim 17, wherein the plating resist portion is formed on the insulation layer or insulating layers each comprising a prepreg.

20: A printed wiring board, comprising:
a plurality of conductive layers having circuit patterns;
a plurality of insulation layers alternately overlaid with the conductive layers; and
a plating resist portion comprising a cured product of the resin composition of claim 3, exposed in an opening of a through-hole and formed on at least one of an interlaminar part between one of the conductive layers and one of the insulation layers and an interlaminar part between the insulation layers.
